(19) United States
(12) Patent Application Publication
(10) Pub. No.: US 2014/0111176 A1
(43) Pub. Date: Apr. 24, 2014

(54) POWER SUPPLY FILTER AND ELECTRONIC CIRCUITRY INCLUDING THE SAME

(71) Applicant: Panasonic Corporation, Kadoma-shi (JP)

(72) Inventor: Toshiro NISHIMURA, Osaka (JP)

(73) Assignee: Panasonic Corporation, Kadoma-shi (JP)

(21) Appl. No.: 14/055,435

(22) Filed: Oct. 16, 2013

(30) Foreign Application Priority Data
Oct. 23, 2012 (JP) 2012-233871
Oct. 10, 2013 (JP) 2013-212807

(51) Int. Cl. H02M 1/14; H03H 7/01

(52) U.S. Cl. CPC H02M 1/14; H03H 7/0138
USPC 323/282; 333/172

(57) ABSTRACT

A power supply filter includes a first filter circuit and a second filter circuit connected in parallel with each other across supply voltage input terminals. The first filter circuit has such a low-pass characteristic that a gain of the first filter circuit is higher than that of the second filter circuit in a first band which is a low band. The second filter circuit includes a serially-inserted resistive element and has such a high-pass characteristic that the gain of the second filter circuit is higher than that of the first filter circuit in a second band which is a high band.

### BACKGROUND

1. Field

The present disclosure relates to a power supply filter.

2. Description of the Related Art

In a switching type DC-DC converter, mainly due to the effect of a parasitic inductor, high-frequency ringing noise, which occurs when power MOSFETs at a high supply voltage side (hereinafter, referred to as “high side”) and a low supply voltage side (hereinafter, referred to as “low side”) are turned OFF, occurs in a frequency band of 100 MHz to several hundreds MHz, and spurious radiation becomes a problem.

In general, as a method for reducing high-frequency noise, a countermeasure method is used in which by inserting a series resistance into a gate drive circuit of a DC-DC converter, rising is made gradual and ringing is reduced.

Meanwhile, in order to reduce the high-frequency noise, for example, a method of connecting a large-capacity bulk capacitor and a small-capacity capacitor for a countermeasure against noise in parallel at an input stage of a DC-DC converter has also been proposed. In this technology, by adding the small-capacity capacitor, high-frequency noise is reduced while a driving pulse of a power supply is stabilized (e.g., see Japanese Laid-Open Patent Publication No. 2006-262121).

### SUMMARY

However, in the former method, due to heat generation of the power MOSFETs and increase in power loss of the gate drive, the power supply efficiency is decreased. In the latter method, high-frequency noise is absorbed to some extent by the small-capacity capacitor, but it is difficult to reduce high-frequency noise to a desired level for an apparatus affected greatly by noise.

For example, a laptop PC needs a DC-DC converter for each load, and thus it is necessary to reduce high-frequency noise generated from each power source. Furthermore, with size reduction of apparatuses and the like, size reduction of circuit boards is also desired. In order to reduce a circuit board in size, it is generally effective to increase a driving frequency of a power supply voltage. However, if the driving frequency is increased, an adverse effect occurs that high-frequency noise is increased and a stable operation of an apparatus becomes difficult. Thus, there is a desire for a means for further reducing high-frequency noise, in order to allow a stable operation to be performed even when the driving frequency of the power supply voltage is increased. In recent years, increase in the number of processes for countermeasures against EMI is a problem, and there is an urgent need to take measures against the problem.

A power supply filter which efficiently reduces high-frequency noise and electronic circuitry including the same are provided herein.

In one general aspect, the techniques disclosed here feature a power supply filter includes a first filter circuit and a second filter circuit connected in parallel with each other across supply voltage input terminals. The first filter circuit has such a low-pass characteristic that a gain of the first filter circuit is higher than that of the second filter circuit in a first band which is a low band, and the second filter circuit includes a serially-inserted resistive element and has such a high-pass characteristic that the gain of the second filter circuit is higher than that of the first filter circuit in a second band which is a high band.

According to the above configuration, since the resistive element is inserted in series into the second filter circuit, a current of high-frequency noise absorbed by the second capacitor is sufficiently attenuated by the resistive element. Thus, it is possible to sufficiently suppress spurious radiation generated by a current loop of the high-frequency noise. Due to the above, it is possible to provide a power supply filter which is able to efficiently reduce high-frequency noise.

Additional benefits and advantages of the disclosed embodiments will be apparent from the specification and Figures. The benefits and/or advantages may be individually provided by the various embodiments and features of the specification and drawings disclosure, and need not all be provided in order to obtain one or more of the same.

### BRIEF DESCRIPTION OF THE DRAWINGS

FIG. 1 is a circuit diagram showing the configuration of a first DC-DC converter including a power supply filter according to the present disclosure;

FIG. 2 is a graph illustrating impedance-frequency characteristics of capacitors used in the power supply filter in FIG. 1;

FIG. 3 is a diagram showing the present disclosure, FIG. 3(a) shows an ideal switching output waveform of the DC-DC converter, and FIG. 3(b) shows a converter output waveform obtained from the switching waveform in FIG. 3(a);

FIG. 4 is a diagram showing the present disclosure, FIG. 4(a) shows a switching output waveform of the DC-DC converter when the DC-DC converter is affected by a circuit parasitic component that a board has, and FIG. 4(b) shows a converter output waveform obtained from the switching waveform in FIG. 4(a);

FIG. 5 is a diagram showing a comparative example according to the present disclosure, FIG. 5(a) shows a switching output waveform of the DC-DC converter when the DC-DC converter is affected by circuit parasitic components that the board and components have, and FIG. 5(b) shows a converter output waveform obtained from the switching waveform in FIG. 5(a);

FIG. 6 is a diagram showing a relationship between a degree of occurrence of ringing occurring in an output waveform of the DC-DC converter according to the present disclosure and a frequency spectrum of the output waveform; and

FIG. 7 is a circuit diagram showing the configuration of a second DC-DC converter including the power supply filter according to the present disclosure.

### DETAILED DESCRIPTION

Hereinafter, the present disclosure will be described in detail with reference to the drawings.

In the present disclosure, according to a second aspect based on the above-described aspect (first aspect), the power supply filter can be configured in which a resistance value of the resistive element is not lower than 0.1Ω.

In addition, in the present disclosure, according to a third aspect based on the second aspect, the power supply filter can be configured in which the resistance value of the resistive element is not lower than 0.5Ω and not higher than 1Ω.

In addition, in the present disclosure, according to a fourth aspect based on any one of the first to third aspects, the power supply filter can be configured in which the first filter circuit is composed of a first capacitor, the second filter circuit is composed of a second capacitor and the resistive element which are connected in series, and a capacitance value of the first capacitor is higher than a capacitance value of the second capacitor.

In addition, in the present disclosure, according to a fifth aspect based on the fourth aspect, the power supply filter can be configured in which the capacitance value of the first capacitor is within a range of 10 μF to 100 μF, and the capacitance value of the second capacitor is within a range of 0.01 μF to 0.1 μF.

In addition, in the present disclosure, according to a sixth aspect based on the fourth aspect, the power supply filter can be configured in which the second filter circuit is an ESR (Equivalent Series Resistance) capacitor having a capacitive element as the second capacitor and an equivalent series resistance as the resistive element.

In addition, in the present disclosure, according to a seventh aspect, electronic circuitry can be configured to include the power supply filter according to any one of the first to sixths aspects and a circuit configured to switch a supply voltage inputted via the power supply filter.

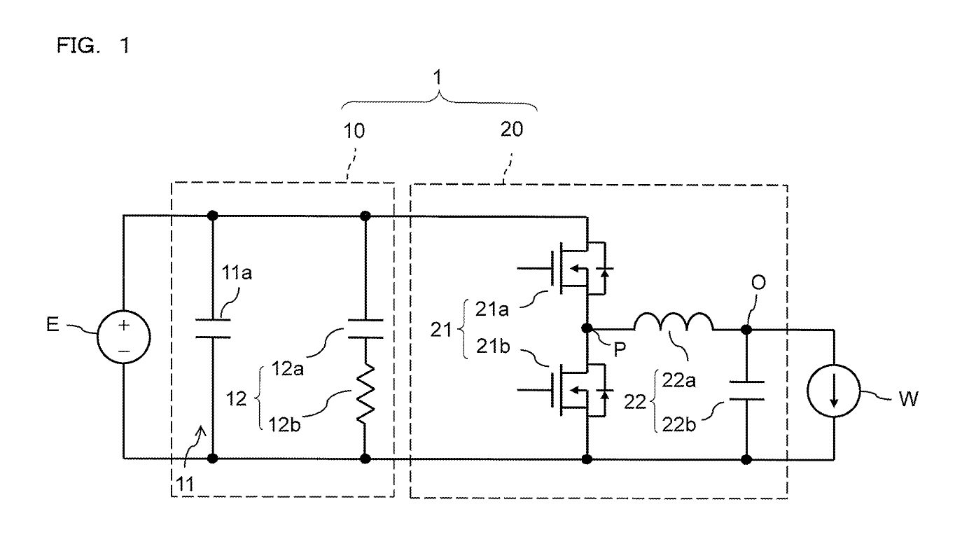

FIG. 1 shows the configuration of a DC-DC converter 1 including a power supply filter according to the present disclosure.

The DC-DC converter 1 is a step-down converter and includes a power supply filter 10 and a voltage conversion stage 20.

The power supply filter 10 includes a first filter circuit 11 and a second filter circuit 12. The first filter circuit 11 and the second filter circuit 12 are connected to two supply lines, fed from a DC power source E, in parallel with each other across supply voltage input terminals.

The first filter circuit 11 is composed of a first capacitor 11a. The first capacitor 11a is a capacitor classified generally as a large-capacity capacitor, such as an aluminum electrolytic capacitor, a functional polymer capacitor, or a ceramic capacitor.

The second filter circuit 12 is composed of a second capacitor 12a and a resistive element 12b. The second capacitor 12a and the resistive element 12b are connected in series across the supply voltage input terminals. The second capacitor 12a is a capacitor having a smaller capacity than that of the first capacitor 11a, such as a multilayer capacitor having a low equivalent series resistance (ESR). In addition, for example, the second capacitor 12a is a capacitive element which has a smaller capacity than that of the first capacitor 11a and is included in an ESR capacitor having an ESR whose value is built into itself under control. The resistive element 12b is composed of, for example, a discrete resistive element, a resistor monolithically integrated into the second capacitor 12a, or an ESR produced in an ESR capacitor. Here, as an example, the second filter circuit 12 is composed of an ESR capacitor having a capacitive element as the second capacitor 12a and an ESR as the resistive element 12b. The ESR capacitor is also referred to as high ESR capacitor, and is a capacitor in which the resistance value of an electrode connection portion or an electrode of a capacitive element is controlled and an ESR is added in series to the capacitive element.

For noise having typical frequencies of 100 MHz to 400 MHz, for example, the capacitance value of the first capacitor 11a is set within a range of 10 μF to 100 μF, and the capacitance value of the second capacitor 12a is set within a range of 0.01 μF to 0.1 μF. In addition, the resistance value of the resistive element 12b, including the ESR of the ESR capacitor, has a magnitude that cannot be ignored as compared to the ESR of the first capacitor 11a, and this resistance value is, for example, a value of not lower than 0.1Ω.

The voltage conversion stage 20 includes a switching circuit 21 and a low pass filter 22.

The switching circuit 21 includes a MOSFET 21a, at a high side, which performs switching; and a MOSFET 21b, at a low side, which performs switching. A high-side supply voltage is supplied to the drain of the MOSFET 21a, a low-side supply voltage (e.g., a GND potential) is supplied to the source of the MOSFET 21b. The source of the MOSFET 21a and the drain of the MOSFET 21b are connected to each other as shown at a terminal P. The gates of the MOSFETs 21a and 21b are controlled, for example, by pulse width modulation control, and the MOSFET 21a and the MOSFET 21b perform ON/OFF operations in a manner complementary to each other.

The low pass filter 22 is an LC filter composed of a coil 22a and a capacitor 22b. The coil 22a is connected between the terminal P and an output terminal O at the high side. The capacitor 22b is connected between the output terminal o and an output terminal at the low side. The low pass filter 22 extracts a DC component as a voltage across the capacitor 22b from a pulse voltage outputted from the terminal P. The voltage is outputted as a stepped-down DC voltage to a load W.

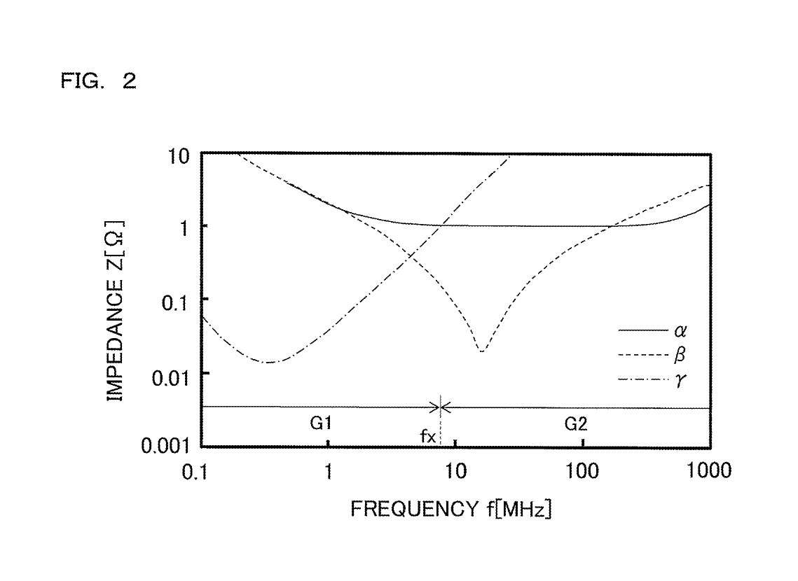

Next, FIG. 2 shows impedance-frequency characteristics of capacitors used in the first filter circuit 11 and the second filter circuit 12.

Hitherto, a capacitor having a low ESR such as a multilayer ceramic capacitor is used as a small-capacity capacitor, for a countermeasure against noise, which is connected in parallel with a large-capacity bulk capacitor. As an impedance-frequency characteristic, a bulk capacitor exhibits a low impedance characteristic relative to a frequency component in the kHz band, for example, like Characteristic γ indicated by a long dashed short dashed line. A capacitor having a low ESR exhibits a low impedance characteristic relative to a frequency component in the MHz band, for example, like Characteristic β indicated by a dashed line. When the capacitor having a low ESR is used as the small-capacity capacitor, the ESR also has a low value of less than about 0.1Ω relative to noise having typical frequencies of 100 MHz to 400 MHz, and thus a current caused by high-frequency noise and flowing through the small-capacity capacitor is relatively high. Therefore, spurious radiation caused by a current loop via the small-capacity capacitor has an adverse effect on an apparatus.

Thus, when an ESR capacitor having a high ESR is used in the second filter circuit 12, the ESR capacitor exhibits, as an impedance-frequency characteristic, a characteristic which is close to a flat characteristic and maintains a high value of not lower than 0.1Ω in a wide frequency range, for example, like Characteristic α indicated by a solid line. Therefore, when a first capacitor 11a having Characteristic γ is used in the first filter circuit 11 and an ESR capacitor having Characteristic α is used in the second filter circuit 12, the following characteristics are obtained as characteristics of the power supply filter 10. Specifically, where the frequency of the intersection between Characteristic α and Characteristic γ is fx, the gain of Characteristic γ is higher than the gain of Characteristic a in a first band G1 which covers frequencies lower than the frequency fx, typically a kHz range and lower, and the gain of Characteristic α is higher than the gain of Characteristics γ in a second band G2 which covers frequencies higher than the frequency fx, typically a MHz range.

As described above, the first filter circuit 11 has such a low-pass characteristic that the gain of the first filter circuit 11 is higher than that of the second filter circuit 12 in the first band G1 which is a low band, and the second filter circuit 12 has such a high-pass characteristic that the gain of the second filter circuit 12 is higher than that of the first filter circuit 11 in the second band G2 which is a high band. Since the resistive element 12b is inserted in series in the second filter circuit 12, a current of high-frequency noise absorbed by the second capacitor 12a is sufficiently attenuated by the resistive element 12b. Thus, it is possible to sufficiently suppress generation of spurious radiation duet to a current loop of the high-frequency noise. Since the power supply filter 10 is provided, it is possible to selectively reduce high-frequency noise on the supply lines. Due to the above, it is possible to provide a power supply filter which is able to efficiently reduce high-frequency noise.

It should be noted that the first band G1 may be a part of a frequency range lower than the frequency fx, and the second band G2 may be a part of a frequency range higher than the frequency fx. Therefore, the used first band G1 and the used second band G2 may not be adjacent to each other at the frequency fx, and may be generated so as to be away from the frequency fx. In other words, it is possible to generate, at the low-frequency side, one or more bands in which the gain of the first filter circuit 11 is higher than that of the second filter circuit 12, and to generate, at the high-frequency side, one or more bands in which the gain of the second filter circuit 12 is higher than that of the first filter circuit 11, and it suffices that at least one or more frequency ranges applicable to the first band G1 and the second band G2 respectively are included. It is possible to realize such frequency characteristics of the gain by setting the filter constants of the first filter circuit 11 and the second filter circuit 12 according to the frequency of to-be-absorbed noise through combination of optional elements.

In addition, when an ESR capacitor having an ESR as the resistive element 12b is used in the second filter circuit 12, it is possible to produce the resistive element 12b simultaneously with the second capacitor 12a, and it is not necessary to separately mount the resistive element 12b at a stage subsequent to the second capacitor 12a. Therefore, it is possible to reduce the number of components.

It should be noted that each of Characteristics α to γ changes depending on (1) circuit conditions such as a capacitance value and an applied voltage, (2) the size and the distribution of an RLC parasitic component of the circuit, (3) usage environment such as the ambient temperature, etc. However, since the ESR of Characteristic α is arbitrarily controllable according to design at the time of manufacture, it is possible to design the first band G1 and the second band G2 according to a desired condition under which the power supply filter 10 is used. In addition, when the low-frequency side and the high-frequency side are separated at about 1 MHz as their boundary, it is easy to configure the first filter circuit 11 and the second filter circuit 12 using general-purpose elements, and it is possible to deal with almost all of ordinary switching noise frequencies at the high-frequency side by the second filter circuit 12 and also deal with almost all of the other noise frequencies at the low-frequency side.

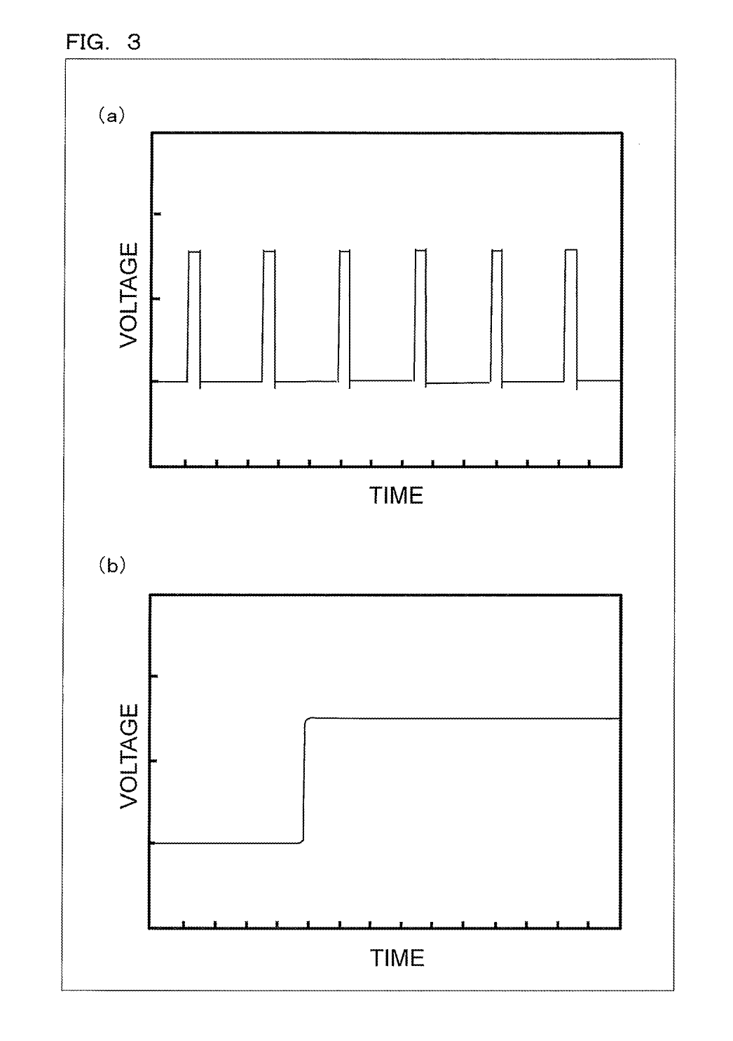

Next, an effect of the power supply filter 10 on ringing occurrence will be described with reference to FIGS. 3 to 6.

FIG. 3 shows ideal voltage waveforms when noise is not mixed in a supply voltage. FIG. 3(a) shows a switching output waveform at the terminal P of the voltage conversion stage 20, and FIG. 3(b) shows a voltage waveform at the output terminal O of the voltage conversion stage 20. Values in the vertical axes and the horizontal axes are arbitrarily designable, and the specific indication is omitted.

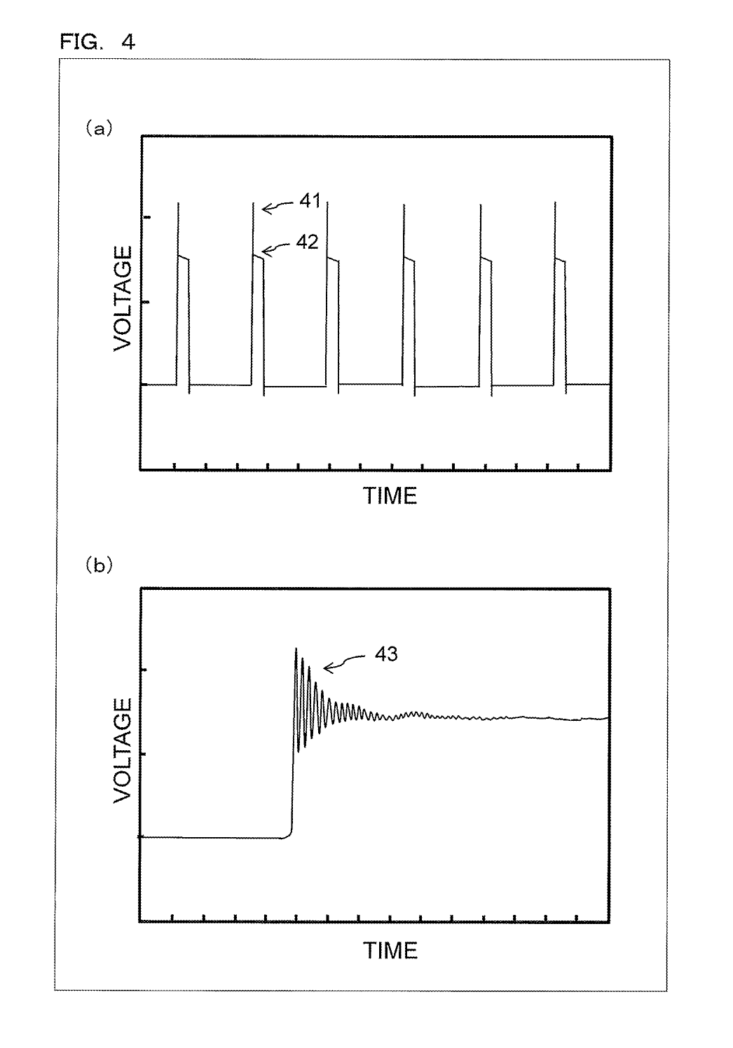

FIG. 4 shows voltage waveforms when a DC-DC converter that does not include the power supply filter 10 is affected by a circuit parasitic component that a board has. FIG. 4(a) shows a switching output waveform at the terminal P. A spike 41 occurs and a sag 42 also occurs at each time of pulse rising. FIG. 4(b) shows a voltage waveform at the output terminal O. Ringing 43 occurs at the time of output voltage rising.

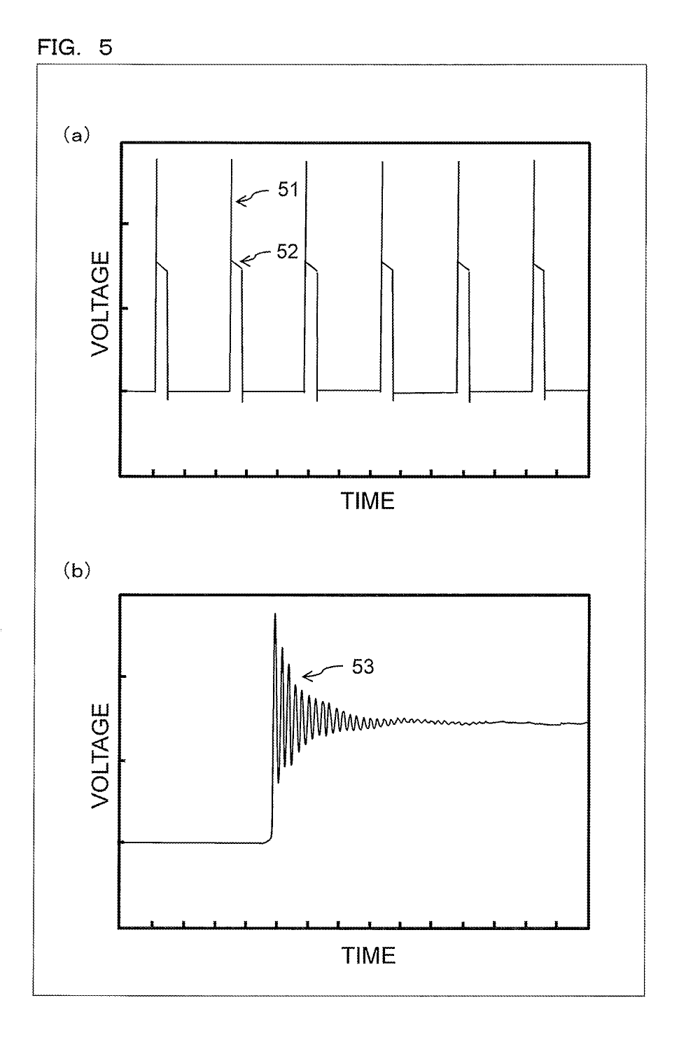

FIG. 5 shows voltage waveforms when the DC-DC converter that does not include the power supply filter 10 is affected by circuit parasitic components that the board and a component have. FIG. 5(a) shows a switching output waveform at the terminal P. At each time of pulse rising, a spike 51 larger than that in FIG. 4(a) occurs, and a sag 52 steeper than that in FIG. 4(a) occurs. FIG. 5(b) shows a voltage waveform at the output terminal O. At the time of output voltage rising, ringing 53 having larger amplitude and longer duration than those in FIG. 4(b) occurs.

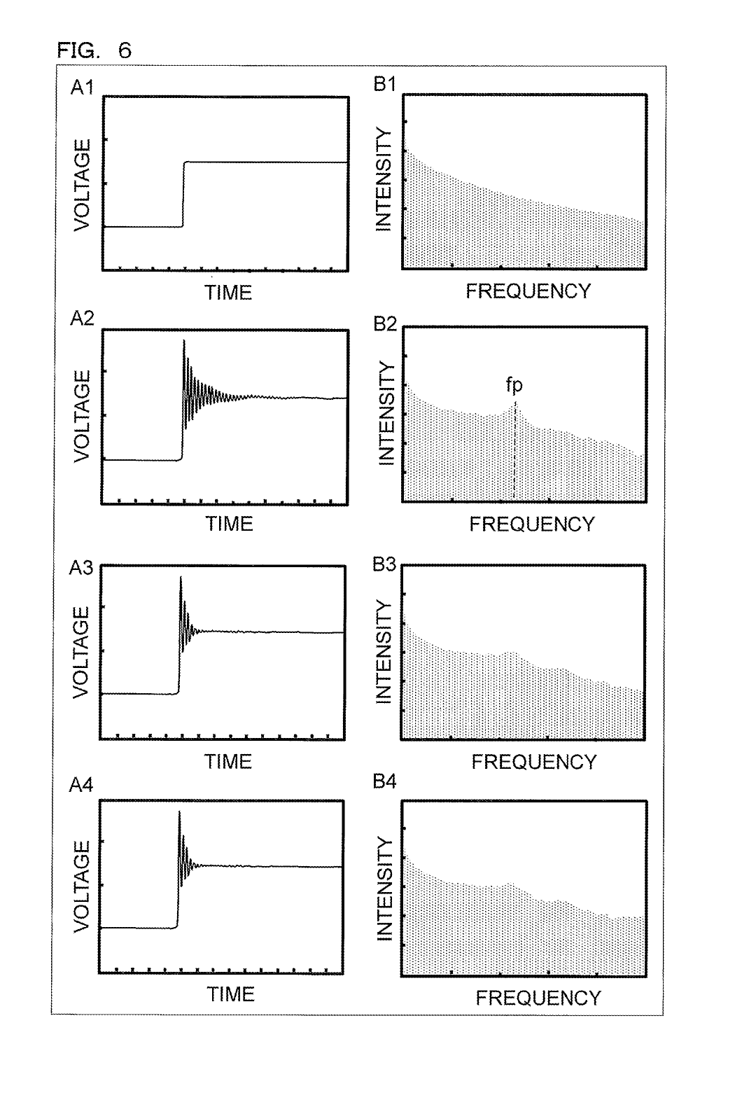

FIG. 6 shows a relationship between a degree of occurrence of ringing occurring in an output waveform of the DC-DC converter and a frequency spectrum of the output waveform.

A1 shows the ideal output voltage waveform in FIGS. 3(b), and B1 shows a frequency spectrum of the output voltage waveform in A1.

A2 shows an output voltage waveform of the DC-DC converter when a small-capacity capacitor having an ESR of about 0.001Ω which is sufficiently lower than 0.1Ω is used in the power supply filter 10 instead of the second filter circuit 12, and B2 shows a frequency spectrum of the output voltage waveform in A2.

A3 shows an output voltage waveform of the DC-DC converter 1 when an ESR capacitor having an ESR of 0.5Ω is used in the second filter circuit 12 in the power supply filter 10, and B3 shows a frequency spectrum of the output voltage waveform in A3.

A4 shows an output voltage waveform of the DC-DC converter 1 when an ESR capacitor having an ESR of 1.0Ω is used in the second filter circuit 12 in the power supply filter 10, and B4 shows a frequency spectrum of the output voltage waveform in A4.

In B2, a parallel resonance peak is observed at a specific frequency fp. The frequency fp is typically present within a range of 100 MHz to 300 MHz. In contrast, the magnitude and the duration of the ringing are sufficiently attenuated in A3 and A4, and the peak at the frequency fp is attenuated in B3 and B4. No significant difference in degree of ringing is observed between A3 and A4, and the same also applies to the power supply filter 1 having an ESR value between the ESR values in A3 and A4.

As described above, according to the power supply filter 10 of the present disclosure, ringing noise in the DC-DC converter 1 is divided into low-frequency noise and high-frequency noise by the capacitor at the input side, and only the high-frequency noise which causes spurious radiation by a current loop is absorbed by the ESR capacitor. Thus, it is possible to reduce the ringing noise without decreasing the efficiency. In addition, it is made possible to reduce high-frequency ringing noise without decreasing the power supply efficiency due to heat generation of the power MOSFETs used as switching transistors in the DC-DC converter and power loss of the gate drive, and it is made possible to take countermeasures against noise in an apparatus at an early stage of development.

When the resistance value of the resistive element 12b, including the ESR of the ESR capacitor, is set within a range of 0.1Ω to 1Ω, it is possible to favorably attenuate high-frequency noise, and in particular, when the resistance value of the resistive element 12b is set within a range of 0.5Ω to 1Ω, it is possible to favorably remove high-frequency noise.

For noise having typical frequencies such as 100 MHz to 400 MHz, the capacitance values of the first capacitor 11a and the second capacitor 12a are exemplified as described above. However, regarding a circuit configuration in which the switching noise frequency exceeds 400 MHz, even when these capacitance values are changed, since the impedance-frequency characteristic of the ESR capacitor shows approximately flat behavior at least up to around 1000 MHz as shown in FIG. 2, less design change is merely needed to keep the high-frequency noise attenuation effect. As described above, the configuration of the power supply filter 10 is a configuration with which an advantageous effect is generally obtained with respect to switching frequencies in a wide band. In the circuit configuration in which the switching noise frequency exceeds 400 MHz, the necessity to steepen pulse rising may arise since the interval of a pulse generated by switching is very small, but steep pulse rising becomes a factor for increasing ringing due to an L·di/dt effect in the circuit. Thus, the fact that there is no need to change the basic configuration of the power supply filter 10 makes designing and manufacturing easy.

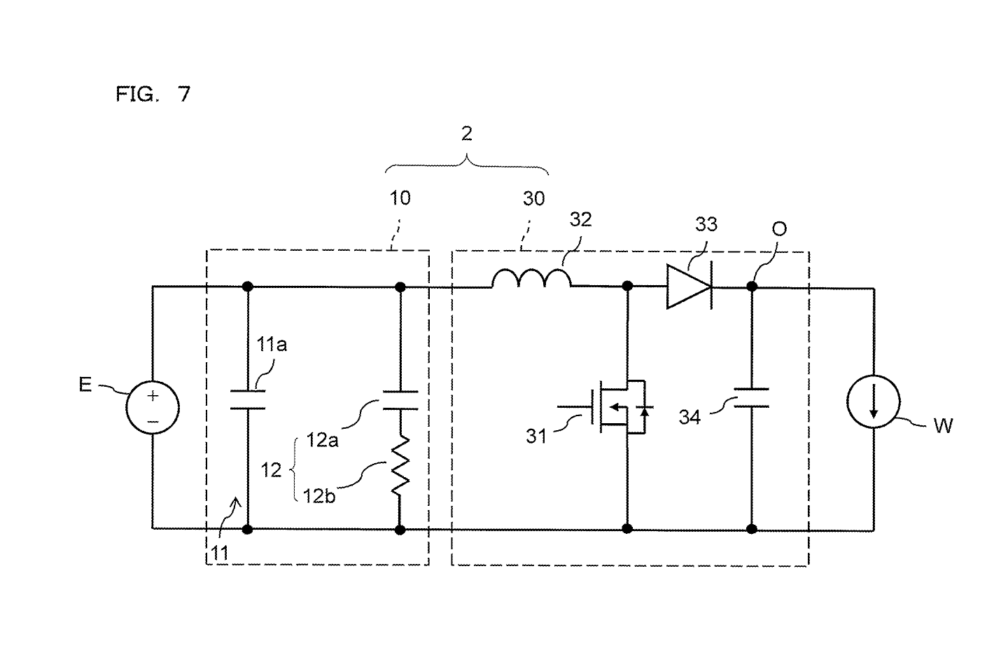

Next, FIG. 7 shows the configuration of another DC-DC converter 2 including the power supply filter according to the present disclosure. Components having the same functions as those in the DC-DC converter 1 in FIG. 1 are designated by the same reference characters, and the description thereof is omitted.

The DC-DC converter 2 is a step-up converter and includes a power supply filter 10 and a voltage conversion stage 30.

The voltage conversion stage 30 includes a MOSFET 31, a coil 32, a diode 33, and a capacitor 34. An end of the coil 32 is connected to a high side of a supply line, and the other end of the coil 32 is connected to the anode of the diode 33. The drain of the MOSFET 31 is connected to a connection point between the coil 32 and the diode 33, and the source of the MOSFET 31 is connected to a low side of the supply line (e.g., GND). One terminal of the capacitor 34 is connected to the cathode of the diode 33 and constitutes an output terminal O of the voltage conversion stage 30. The other terminal of the capacitor 34 is connected to the low side of the supply line.

A voltage which is supplied from a DC power source E and from which noise is removed by the power supply filter 10 is inputted to the voltage conversion stage 30. When the MOSFET 31 is OFF, initial charging is performed on the capacitor 34 via the coil 32 and the diode 33. Next, when the MOSFET 31 is turned ON, a current flowing through the coil 32 flows to the MOSFET 31 side. In a subsequent OFF period of the MOSFET 31, a back electromotive force of the coil 32 is added to the supply voltage, and the supply voltage flows into the capacitor 34 via the diode 33, whereby boosting is performed. Thereafter, as long as the voltage between the terminals of the capacitor 34 is higher than that at the anode side of the diode 33, the diode 33 is kept OFF. If the voltage between the terminals of the capacitor 34 falls, a boosted voltage adjusted by controlling the duty factor of the MOSFET 31 and supplying electric charge for the deficiency in the forward direction of the diode 33 is outputted from the output terminal O to a load W.

Also in the DC-DC converter 2, the same advantageous effects as those described for the DC-DC converter 1 are obtained by the power supply filter 10.

In addition, the power supply filter 10 is able to obtain the same advantageous effects as long as it is electronic circuitry including a circuit which switches an input of a DC power source. Examples of such electronic circuitry include, in addition to a DC-DC converter, an inverter, an AC-DC converter having a configuration in which a rectified supply voltage is used, etc.

The present disclosure is applicable to a circuit which performs switching with a DC voltage as an input, such as a voltage converter and an inverter.

While the disclosure has been described in detail, the foregoing description is in all aspects illustrative and not restrictive. It will be understood that numerous other modifications and variations can be devised without departing from the scope of the disclosure.

What is claimed is:

1. A power supply filter comprising:
a first filter circuit and a second filter circuit connected in parallel with each other across supply voltage input terminals, wherein
the first filter circuit has such a low-pass characteristic that a gain of the first filter circuit is higher than that of the second filter circuit in a first band which is a low band, and
the second filter circuit includes a serially-inserted resistive element and has such a high-pass characteristic that the gain of the second filter circuit is higher than that of the first filter circuit in a second band which is a high band.

2. The power supply filter according to claim 1, wherein a resistance value of the resistive element is not lower than 0.1Ω.

3. The power supply filter according to claim 2, wherein the resistance value of the resistive element is not lower than 0.5Ω and not higher than 1Ω.

4. The power supply filter according to claim 1, wherein
the first filter circuit is composed of a first capacitor,
the second filter circuit is composed of a second capacitor and the resistive element which are connected in series, and
a capacitance value of the first capacitor is higher than a capacitance value of the second capacitor.

5. The power supply filter according to claim 4, wherein
the capacitance value of the first capacitor is within a range of 10 μF to 100 μF, and
the capacitance value of the second capacitor is within a range of 0.01 μF to 0.1 μF.

6. The power supply filter according to claim 4, wherein the second filter circuit is an ESR (Equivalent Series Resistance) capacitor having a capacitive element as the second capacitor and an equivalent series resistance as the resistive element.

7. Electronic circuitry comprising:
the power supply filter according to claim 1; and
a circuit configured to switch a supply voltage inputted via the power supply filter.
